(19) United States
(12) Patent Application Publication
(10) Pub. No.: US 2012/0038435 A1
(43) Pub. Date: Feb. 16, 2012

(54) ELASTIC WAVE APPARATUS

(75) Inventors: Masaru YATA, Nagaokakyo-shi (JP); Shinichi SOGOYA, Nagaokakyo-shi (JP); Yasuhisa FUJII, Nagaokakyo-shi (JP); Masakazu MIMURA, Nagaokakyo-shi (JP)

(73) Assignee: MURATA MANUFACTURING CO., LTD., Nagaokakyo-shi (JP)

(21) Appl. No.: 13/282,558

(22) Filed: Oct. 27, 2011

Related U.S. Application Data
(63) Continuation of application No. PCT/JP2010/056859, filed on Apr. 16, 2010.

(30) Foreign Application Priority Data
Apr. 30, 2009 (JP) 2009-110758

(51) Int. Cl. H03H 9/17

(52) U.S. Cl. 333/187

(57) ABSTRACT

In an elastic wave apparatus, a first dielectric layer is laminated on a piezoelectric substrate. An electrode structure is provided at an interface between the first dielectric layer and the piezoelectric substrate. The electrode structure includes a first electrode structure of an elastic wave filter and a second electrode structure of elastic wave resonators. The elastic wave resonators are electrically connected to the elastic wave filter. An anti-resonant frequency at which the extreme impedance values of the elastic wave resonators are obtained is in a frequency band in which the higher-order mode spurious response of the elastic wave filter appears.

### BACKGROUND OF THE INVENTION

1. Field of the Invention

The present invention relates to elastic wave apparatuses used in resonators and bandpass filters, and, more particularly, to an elastic wave apparatus that suppresses a higher-order mode spurious response.

2. Description of the Related Art

Surface acoustic wave apparatuses using a surface acoustic wave are widely used as bandpass filters and resonators. In place of surface acoustic wave apparatuses, boundary acoustic wave apparatuses using a boundary acoustic wave with which miniaturization can be achieved are attracting attention.

For example, International Publication No. WO 98/52279 discloses a boundary acoustic wave apparatus having a three-medium structure in which a polycrystalline silicon oxide film and a polycrystalline silicon film are laminated on a piezoelectric substrate in this order and an IDT electrode is disposed at the interface between the piezoelectric substrate and the polycrystalline silicon oxide film. International Publication No. WO 98/52279 states that a boundary acoustic wave excited by the IDT electrode is confined in the polycrystalline silicon oxide film and the boundary acoustic wave apparatus has an electrical characteristic that is superior to that of a surface acoustic wave apparatus in the related art even if the quality of the polycrystalline silicon film is deteriorated.

In elastic wave apparatuses including the above-described boundary acoustic wave apparatus, the fundamental mode of an elastic wave to be used can be confined well. However, since the higher-order mode of the elastic wave is also confined within the polycrystalline silicon oxide film, the higher-order mode results in a spurious response.

### SUMMARY OF THE INVENTION

To overcome the problems described above, preferred embodiments of the present invention provide an elastic wave apparatus capable of effectively suppressing a higher-order mode spurious response and providing a good filter characteristic.

An elastic wave apparatus according to a preferred embodiment of the present invention preferably includes a piezoelectric substrate, a first dielectric layer provided on the piezoelectric substrate, and an electrode structure provided at an interface between the piezoelectric substrate and the first dielectric layer. The electrode structure preferably includes a first electrode structure of an elastic wave filter and a second electrode structure of an elastic wave resonator. A frequency at which an extreme value of a frequency characteristic of the elastic wave resonator is obtained is preferably located in a frequency band in which a higher-order mode spurious response appears in a frequency characteristic of the elastic wave filter.

In a preferred embodiment of the present invention, the elastic wave resonator is preferably connected in series to the elastic wave filter and an anti-resonant frequency of the elastic wave resonator is located in the frequency band in which the higher-order mode spurious response appears. In this case, since the highest impedance is obtained at the anti-resonant frequency of the elastic wave resonator, the higher-order mode spurious response of the elastic wave filter is effectively suppressed using the impedance characteristic of the elastic wave resonator that is connected in series to the elastic wave filter.

In another preferred embodiment of the present invention, the elastic wave resonator is preferably connected in parallel to the elastic wave filter and a resonant frequency of the elastic wave resonator is located in the frequency band in which the higher-order mode spurious response appears. In this case, the minimum impedance value is obtained at the resonant frequency of the elastic wave resonator. However, since the elastic wave resonator is connected in parallel to the elastic wave filter, the higher-order mode spurious response of the elastic wave filter is effectively suppressed using the impedance characteristic of the elastic wave resonator at the resonant frequency.

The elastic wave apparatus may preferably further include another elastic wave resonator connected in series to the elastic wave filter in addition to the elastic wave resonator connected in parallel to the elastic wave filter. An anti-resonant frequency of the other elastic wave resonator that is connected in series to the elastic wave filter is located in the frequency band in which the higher-order mode spurious response appears. In this case, the higher-order mode spurious response of the elastic wave filter is more effectively suppressed by the elastic wave resonator connected in parallel to the elastic wave filter and the other elastic wave resonator connected in series to the elastic wave filter.

In still another preferred embodiment of the present invention, a plurality of the elastic wave resonators whose poles are placed in the frequency band in which the higher-order mode spurious response appears are preferably provided, and a frequency at the pole of at least one of the plurality of the elastic wave resonators is different from a frequency at the poles of the other ones of the plurality of the elastic wave resonators. In this case, since all of the frequencies at which the extreme frequency characteristic values of these elastic wave resonators are obtained are not the same, the higher-order mode spurious response is suppressed in a wider range in the frequency band in which the higher-order mode spurious response appears.

The structure of the elastic wave filter in the elastic wave apparatus according to various preferred embodiments of the present invention is not particularly limited. In still another preferred embodiment of the present invention, the elastic wave filter is preferably a longitudinally coupled resonator-type elastic wave filter. In this case, the electrode structure of a filter portion can be miniaturized. Accordingly, it is possible to provide a small elastic wave apparatus.

In still another preferred embodiment of the present invention, a second dielectric layer laminated on the first dielectric layer is preferably further provided. In such an elastic wave apparatus having a three-medium structure, a large higher-order mode spurious response is likely to appear at an elastic wave filter portion. However, according to various preferred embodiments of the present invention, the higher-order mode spurious response can be effectively suppressed.

In an elastic wave apparatus according to various preferred embodiments of the present invention, the electrode structure preferably includes the first electrode structure and the second electrode structure, so that an elastic wave filter and an elastic wave resonator are connected. A frequency at which the extreme value of the frequency characteristic of the elastic wave resonator is obtained is located in a frequency band in which a higher-order mode spurious response appears in the frequency characteristic of the elastic wave filter. Accordingly, the higher-order mode spurious response is effectively suppressed, and a good filter characteristic can be obtained.

The above and other elements, features, steps, characteristics, and advantages of the present invention will become more apparent from the following detailed description of the preferred embodiments with reference to the attached drawings.

### BRIEF DESCRIPTION OF THE DRAWINGS

FIG. 1 is a schematic plan view illustrating the electrode structure of a boundary acoustic wave apparatus according to a first preferred embodiment of the present invention.

FIG. 2A is a schematic front cross-sectional view illustrating a boundary acoustic wave apparatus according to the first preferred embodiment of the present invention, and FIG. 2B is a schematic enlarged front cross-sectional view in which a portion represented by an ellipse A in FIG. 2A is enlarged.

FIG. 3 is a schematic plan view illustrating the electrode structure of a boundary acoustic wave apparatus in the related art that is prepared for comparison.

FIG. 4 is a diagram illustrating the transmission characteristics of a boundary acoustic wave apparatus according to the first preferred embodiment of the present invention and a boundary acoustic wave apparatus in the related art.

FIG. 5 is a diagram illustrating the impedance-frequency characteristic of a boundary acoustic wave resonator according to the first preferred embodiment of the present invention.

FIG. 6 is a diagram illustrating the phase-frequency characteristic of a boundary acoustic wave resonator according to the first preferred embodiment of the present invention.

FIG. 7 is a diagram illustrating the transmission characteristics of boundary acoustic wave apparatuses according to the first preferred embodiment of the present invention and a second preferred embodiment of the present invention.

FIG. 8 is a diagram illustrating the impedance-frequency characteristic of a boundary acoustic wave resonator according to the second preferred embodiment of the present invention.

FIG. 9 is a diagram illustrating the phase-frequency characteristic of a boundary acoustic wave resonator according to the second preferred embodiment of the present invention.

FIG. 10 is a schematic plan view illustrating the electrode structure of a boundary acoustic wave apparatus according to a third preferred embodiment of the present invention.

FIG. 11 is a diagram illustrating the transmission characteristics of a boundary acoustic wave apparatus according to the third preferred embodiment of the present invention and a boundary acoustic wave apparatus in the related art.

FIG. 12 is a diagram illustrating the impedance-frequency characteristic of a boundary acoustic wave resonator according to the third preferred embodiment of the present invention.

FIG. 13 is a diagram illustrating the phase-frequency characteristic of a boundary acoustic wave resonator according to the third preferred embodiment of the present invention.

### DETAILED DESCRIPTION OF THE PREFERRED EMBODIMENTS

Preferred embodiments of the present invention will be described in detail below with reference to the accompanying drawings.

### First Preferred Embodiment

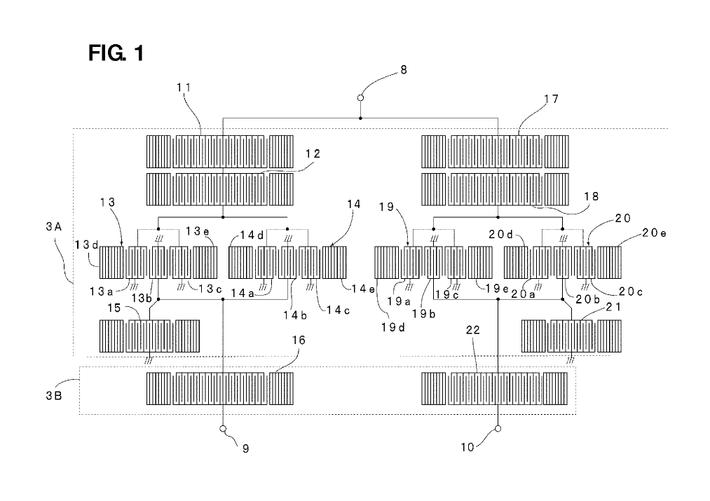

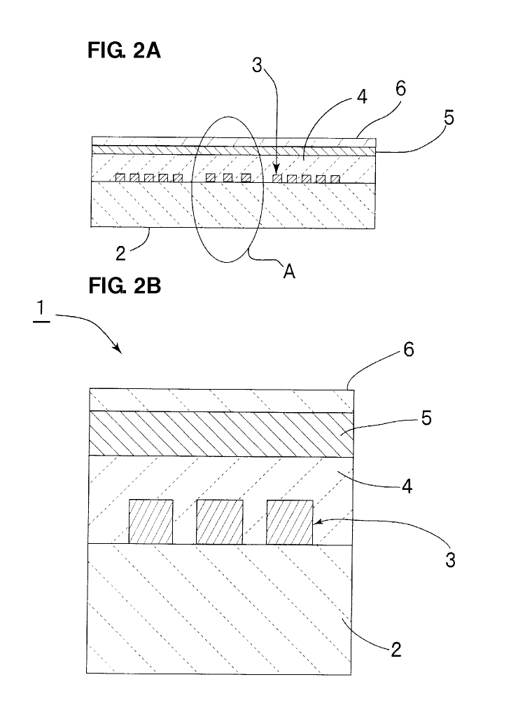

FIG. 1 is a schematic plan view illustrating the electrode structure of a boundary acoustic wave apparatus that is an elastic wave apparatus according to the first preferred embodiment of the present invention. FIG. 2A is a schematic partial front cross-sectional view of the boundary acoustic wave apparatus. FIG. 2B is an enlarged front cross-sectional view in which a portion represented by an ellipse A in FIG. 2A is enlarged.

As illustrated in FIGS. 2A and 2B, a boundary acoustic wave apparatus 1 includes a piezoelectric substrate 2. In this preferred embodiment, the piezoelectric substrate 2 is preferably made of a LiNbO₃ monocrystal substrate having an Euler angle (0°, 115°, ψ), for example. An electrode structure 3 is provided on the piezoelectric substrate 2. The electrode structure 3 is illustrated in the schematic plan view in FIG. 1. A first dielectric layer 4 is arranged to cover the electrode structure 3. In this preferred embodiment, the first dielectric layer 4 is preferably made of silicon oxide, for example. A second dielectric layer 5 is provided on the first dielectric layer 4. In this preferred embodiment, the second dielectric layer 5 is preferably made of silicon nitride, for example. The acoustic velocity of the second dielectric layer 5 is preferably higher than that of the first dielectric layer 4.

A sound absorbing layer 6 is provided on the second dielectric layer 5. In this preferred embodiment, the sound absorbing layer 6 is preferably made of polyimide, for example, that is a synthetic resin.

In this preferred embodiment, the electrode structure 3 is preferably formed by laminating a plurality of metal films, a Pt film, an Al film, and a Pt film, for example, in this order from the top.

The electrode structure 3 may be made of other metal materials, and may be formed of a single-layer metal film.

As illustrated in FIG. 1, the electrode structure 3 is connected between an unbalanced terminal 8 and each of a first balanced terminal 9 and a second balanced terminal 10. The electrode structure 3 includes a first electrode structure 3A of a boundary acoustic wave filter and a second electrode structure 3B of a boundary acoustic wave resonator that functions to suppress a higher-order mode spurious response. The electrode structures 3A and 3B will be described in detail below.

A first 3-IDT longitudinally coupled resonator-type boundary acoustic wave filter portion 13 and a second 3-IDT longitudinally coupled resonator-type boundary acoustic wave filter portion 14 are connected to the unbalanced terminal 8 via a first one-port boundary acoustic wave resonator 11 and a second one-port boundary acoustic wave resonator 12.

More specifically, in each of the first boundary acoustic wave resonator 11 and the second boundary acoustic wave resonator 12, a first reflector and a second reflector are disposed on one side and the other side of an IDT electrode, respectively, in a boundary acoustic wave propagation direction. The first boundary acoustic wave resonator 11 and the second boundary acoustic wave resonator 12 are connected in series to each other. The first boundary acoustic wave filter portion 13 and the second boundary acoustic wave filter portion 14 are connected to the IDT electrode of the second boundary acoustic wave resonator 12.

The first boundary acoustic wave filter portion 13 includes a first IDT 13a, a second IDT 13b, and a third IDT 13c disposed along the boundary acoustic wave propagation direction. A reflector 13d and a reflector 13e are disposed on one side and the other side of an area in which the first IDT 13a, the second IDT 13b, and the third IDT 13c are disposed, respectively, in the boundary acoustic wave propagation direction. The first IDT 13a and the third IDT 13c are connected to each other and are then electrically connected to the second boundary acoustic wave resonator 12. The other ends of the first IDT 13a and the third IDT 13c are connected to the ground potential. One end of the second IDT 13b is connected to the ground potential, and the other end thereof is connected to the first balanced terminal 9. A third one-port boundary acoustic wave resonator 15 is connected between the other end of the second IDT 13b and the ground potential. A fourth one-port boundary acoustic wave resonator 16 is connected between the second IDT 13b and the first balanced terminal 9.

On the other hand, the second 3-IDT longitudinally coupled resonator-type boundary acoustic wave filter portion 14 preferably has a configuration similar to that of the first boundary acoustic wave filter portion 13. That is, the second boundary acoustic wave filter portion 14 includes a first IDT 14a, a second IDT 14b, a third IDT 14c, and reflectors 14d and 14e. One ends of the first IDT 14a and the third IDT 14c are connected to each other and are then connected to the second boundary acoustic wave resonator 12, and the other ends thereof are connected to the ground potential. One end of the second IDT 14b is connected to the ground potential, and the other end thereof is connected to the third and fourth boundary acoustic wave resonators.

Accordingly, the first and second longitudinally coupled resonator-type boundary acoustic wave filter portions 13 and 14 are connected in parallel. The fourth boundary acoustic wave resonator 16 is connected in series to the first boundary acoustic wave filter portion 13 and the second boundary acoustic wave filter portion 14 that are connected in parallel.

On the other hand, an electrode structure is similarly provided between the unbalanced terminal 8 and the second balanced terminal 10. That is, similar to the first boundary acoustic wave resonator 11 and the second boundary acoustic wave resonator 12, a fifth boundary acoustic wave resonator 17 and a sixth boundary acoustic wave resonator 18 are connected between the unbalanced terminal 8 and a third boundary acoustic wave filter portion 19 and a fourth boundary acoustic wave filter portion 20. The third boundary acoustic wave filter portion 19 and the fourth boundary acoustic wave filter portion 20 preferably have a configuration similar to that of the first boundary acoustic wave filter portion 13 and the second boundary acoustic wave filter portion 14 except that the phase of an output signal with respect to an input signal is reversed. That is, the third boundary acoustic wave filter portion 19 includes a first IDT 19a, a second IDT 19b, and a third IDT 19c and reflectors 19d and 19e, and the fourth boundary acoustic wave filter portion 20 includes a first IDT 20a, a second IDT 20b, a third IDT 20c and reflectors 20d and 20e.

A seventh boundary acoustic wave resonator 21 is connected between one end of each of the second IDT 19b in the third boundary acoustic wave filter portion 19 and the second IDT 20b in the fourth boundary acoustic wave filter portion 20 and the ground potential. The seventh boundary acoustic wave resonator 21 preferably has a configuration similar to that of the third boundary acoustic wave resonator 15. An eighth boundary acoustic wave resonator 22 is connected between each of the third boundary acoustic wave filter portion 19 and the fourth boundary acoustic wave filter portion 20, which are connected in parallel, and the second balanced terminal 10. The eighth boundary acoustic wave resonator 22 preferably has a configuration similar to that of the fourth boundary acoustic wave resonator 16.

Accordingly, the boundary acoustic wave apparatus 1 is a filter apparatus including the unbalanced terminal 8, the first balanced terminal 9, and the second balanced terminal 10 and having a balanced-to-unbalanced conversion function.

In this preferred embodiment, in the first boundary acoustic wave filter portion 13, the second boundary acoustic wave filter portion 14, the third boundary acoustic wave filter portion 19, and the fourth boundary acoustic wave filter portion 20, a boundary acoustic wave propagation direction ψ is preferably set to about 0°, for example. In the first boundary acoustic wave resonator 11, the second boundary acoustic wave resonator 12, the fifth boundary acoustic wave resonator 17, and the sixth boundary acoustic wave resonator 18, the boundary acoustic wave propagation direction ψ is preferably set to about 19.5°, for example. In the third boundary acoustic wave resonator 15 and the seventh boundary acoustic wave resonator 21, the boundary acoustic wave propagation direction ψ is preferably set to about 0′, for example. In the fourth boundary acoustic wave resonator 16 and the eighth boundary acoustic wave resonator 22, the boundary acoustic wave propagation direction ψ is preferably set to about 0′, for example.

In the first boundary acoustic wave filter portion 13, the second boundary acoustic wave filter portion 14, the third boundary acoustic wave filter portion 19, and the fourth boundary acoustic wave filter portion 20, a narrow-pitch electrode finger portion is preferably provided in an area in which IDTs are adjacent to each other. As is known, the narrow-pitch electrode finger portion is disposed at the end of an IDT, and is a portion in which an electrode finger pitch is relatively narrow.

A key feature of the boundary acoustic wave apparatus according to this preferred embodiment is that the anti-resonant frequency of the boundary acoustic wave resonators 16 and 22 is set so as to conform to a frequency at which a higher-order mode response appears in the boundary acoustic wave filter having the electrode structure 3A. The frequency at which a higher-order mode response appears is a frequency at which the maximum higher-order mode response appears. In this preferred embodiment, a higher-order mode spurious response is suppressed with the anti-resonant frequency of the boundary acoustic wave resonators 16 and 22. The suppression of a higher-order mode spurious response will be described in detail below.

As described previously, the electrode structure 3B includes the electrode structures of the fourth boundary acoustic wave resonator 16 and the eighth boundary acoustic wave resonator 22, and the electrode structure 3A includes the electrode structures of the other portions, that is, the first boundary acoustic wave resonator 11, the second boundary acoustic wave resonator 12, the third boundary acoustic wave resonator 15, the first boundary acoustic wave filter portion 13, the second boundary acoustic wave filter portion 14, the fifth boundary acoustic wave resonator 17, the sixth boundary acoustic wave resonator 18, the seventh boundary acoustic wave resonator 21, the third boundary acoustic wave filter portion 19, and the fourth boundary acoustic wave filter portion 20.

The first boundary acoustic wave resonator 11, the second boundary acoustic wave resonator 12, the third boundary acoustic wave resonator 15, the fifth boundary acoustic wave resonator 17, the sixth boundary acoustic wave resonator 18, and the seventh boundary acoustic wave resonator 21, which are preferably included in this preferred embodiment, may not be provided.

The above-described electrode structures are provided preferably in accordance with the following specifications in which λ represents the wavelength of a propagated boundary acoustic wave.

### Boundary Acoustic Wave Filter Portion 13

Propagation Direction: ψ=about 0 degree

Intersecting Width: about 27λ

Duty: bout 0.50

Reflector 13d: Number of Pairs: 14.5 pairs, Wavelength=about 1.910 μm

First IDT 13a: Number of Pairs: 9.5 pairs, Wavelength=about 1.871 μm, Wavelength of Four Electrode Fingers Adjacent to IDT 13b=about 1.793 μm

Second IDT 13b: Number of Pairs: 19.0 Pairs, Wavelength=about 1.861 μm, Wavelength of Eight Electrode Fingers Adjacent to IDTs 13a and 13c=about 1.802 μm

Third IDT 13c: Number of Pairs: 9.5 pairs, Wavelength=about 1.871 μm, Wavelength of Four Electrode Fingers Adjacent to IDT 13b=about 1.793 μm

Reflector 13e: Number of pairs: 29.5 pairs, Wavelength=about 1.910 μm

The second boundary acoustic wave filter portion 14, the third boundary acoustic wave filter portion 19, and the fourth boundary acoustic wave filter portion 20 have the same or substantially the same configuration as that of the boundary acoustic wave filter portion 13.

### First Boundary Acoustic Wave Resonator 11

Propagation Direction: ψ=about 19.5 degrees

Intersecting Width: about 40λ

Duty: about 0.50

Reflector: Number of Pairs: 14.5 pairs, Wavelength=about 1.814 μm

IDT: Number of Pairs: 69.0 pairs, Wavelength=about 1.814 μm

The second boundary acoustic wave resonator 12, the fifth boundary acoustic wave resonator 17, and the sixth boundary acoustic wave resonator 18 are designed so that they have the same or substantially the same configuration as that of the first boundary acoustic wave resonator 11.

### Third Boundary Acoustic Wave Resonator 15

Propagation Direction: ψ=about 0 degree

Intersecting Width: about 21λ

Duty: about 0.50

Reflector: Number of Pairs: 14.5 pairs, Wavelength=about 1.900 μm

IDT: Number of Pairs: 48.5 pairs, Wavelength=about 1.900 μm

The seventh boundary acoustic wave resonator 21 is designed so that it has the same or substantially the same configuration as that of the third boundary acoustic wave resonator 15.

### Fourth Boundary Acoustic Wave Resonator 16

Propagation Direction: ψ=about 0 degree

Intersecting Width: about 28λ

Duty: about 0.50

Reflector: Number of Pairs: 14.5 pairs, Wavelength=about 1.435 μm

IDT: Number of Pairs: 100 pairs, Wavelength=about 1.435 μm

The eighth boundary acoustic wave resonator 22 is designed so that is has the same or substantially the same configuration as that of the fourth boundary acoustic wave resonator 16.

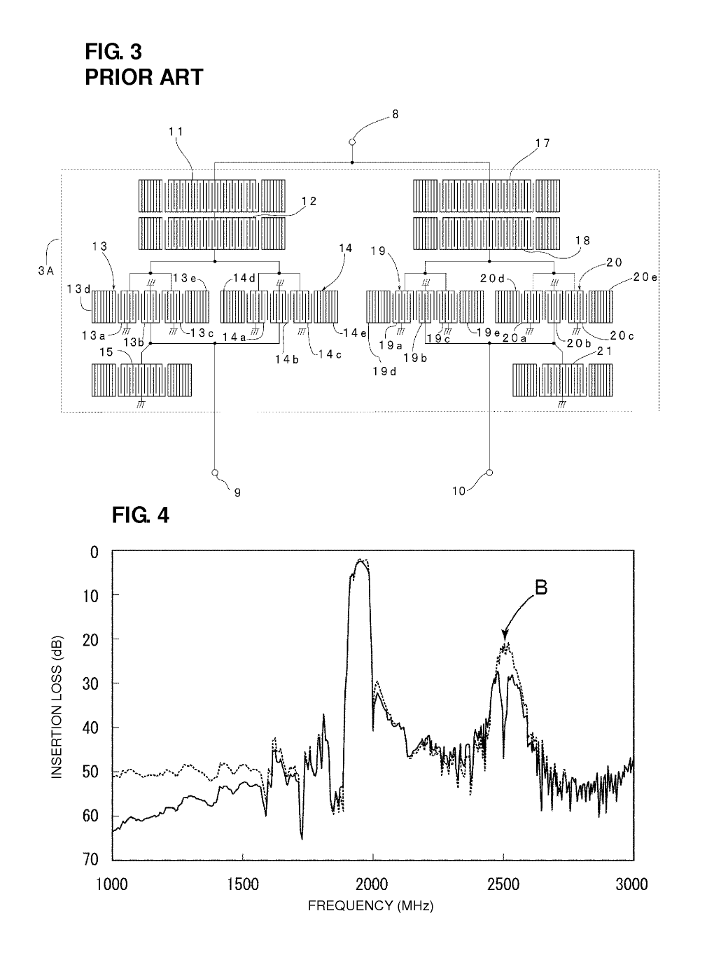

The transmission characteristic, that is, differential characteristic, of the boundary acoustic wave apparatus 1 configured in accordance with the above-described specifications is represented by a solid line in FIG. 4. For comparison, the transmission characteristic of a boundary acoustic wave apparatus in the related art illustrated in FIG. 3 is represented by a broken line in FIG. 4. The boundary acoustic wave apparatus in the related art illustrated in FIG. 3 preferably has the same or substantially the same configuration as that of the boundary acoustic wave apparatus 1 except that the fourth boundary acoustic wave resonator 16 and the eighth boundary acoustic wave resonator 22 are not provided.

As is apparent from FIG. 4, in the related art, the maximum higher-order mode spurious response B appears at approximately 2.5 GHz, and the amount of attenuation is approximately 20 dB. On the other hand, in this preferred embodiment, the amount of attenuation is approximately 27 dB at approximately 2.5 GHz and, thus, is improved by 7 dB. The reason why the amount of attenuation at approximately 2.5 GHz is improved is as follows.

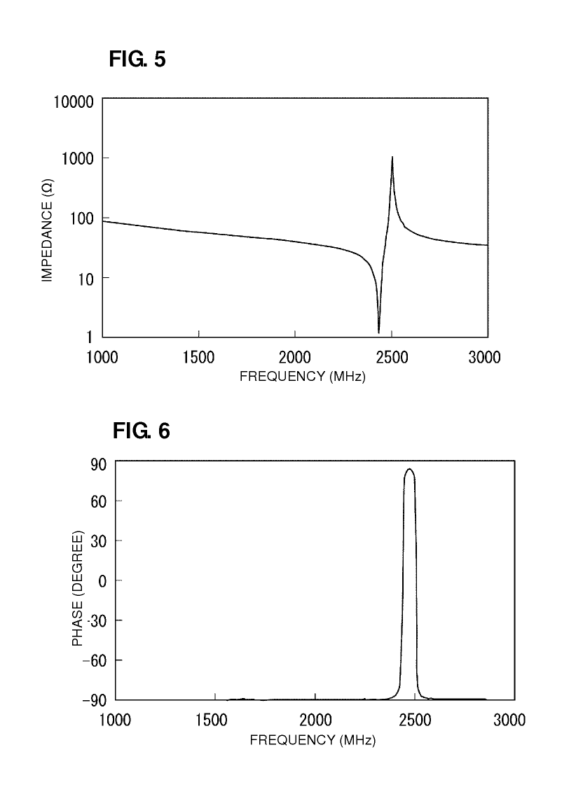

FIGS. 5 and 6 are diagrams illustrating the impedance characteristic and phase characteristic of the fourth boundary acoustic wave resonator 16 used in this preferred embodiment, respectively. The impedance characteristic and phase characteristic of the eighth boundary acoustic wave resonator 22 are the same or substantially the same as those of the fourth boundary acoustic wave resonator 16.

As is apparent from FIGS. 5 and 6, the anti-resonant frequency of the fourth boundary acoustic wave resonator 16 is substantially equal to 2.5 GHz at which the maximum spurious response appears in the transmission characteristic in the related art in FIG. 4.

The fourth boundary acoustic wave resonator 16 is connected in series between each of the first boundary acoustic wave filter portion 13 and the second boundary acoustic wave filter portion 14 and the first balanced terminal 9. The eighth boundary acoustic wave resonator 22 is connected in series between each of the third boundary acoustic wave filter portion 19 and the fourth boundary acoustic wave filter portion 20 and the second balanced terminal 10. The anti-resonant frequency of the fourth boundary acoustic wave resonator 16 and the eighth boundary acoustic wave resonator 22 is approximately 2.5 GHz at which the maximum impedance is obtained. Accordingly, the spurious response that appears at approximately 2.5 GHz in the transmission characteristic of the boundary acoustic wave filter is effectively suppressed.

As is apparent from FIG. 4, the fundamental mode response of a boundary acoustic wave appears at approximately 1.9 GHz. However, in a frequency band around 1.9 GHz, the fourth boundary acoustic wave resonator 16 and the eighth boundary acoustic wave resonator 22 merely operate as capacitors, and therefore, have little effect on the fundamental mode response. Accordingly, it is possible to obtain a good filter characteristic in the fundamental mode and effectively suppress a spurious response at approximately 2.5 GHz that is considered to be a higher-order mode spurious response.

In this preferred embodiment, the anti-resonant frequency of the fourth boundary acoustic wave resonator 16 and the eighth boundary acoustic wave resonator 22 is preferably set so as to conform to a frequency at which the maximum higher-order mode spurious response of a boundary acoustic wave filter appears, but is not necessarily set so as to conform to the frequency. That is, the anti-resonant frequency of the fourth boundary acoustic wave resonator 16 and the eighth boundary acoustic wave resonator 22 may be located in a frequency band in which the above-described higher-order mode spurious response appears. Even if the anti-resonant frequency of the fourth boundary acoustic wave resonator 16 and the eighth boundary acoustic wave resonator 22 slightly deviates from the frequency at which the maximum higher-order mode spurious response appears, the higher-order mode spurious response is still effectively suppressed.

In the first preferred embodiment, preferably, the single-stage fourth boundary acoustic wave resonator 16 is connected in series between each of the first boundary acoustic wave filter portion 13 and the second boundary acoustic wave filter portion 14 and the first balanced terminal 9, and the single-stage eighth boundary acoustic wave resonator 22 is connected in series between each of the third boundary acoustic wave filter portion 19 and the fourth boundary acoustic wave filter portion 20 and the second balanced terminal 10. However, a plurality of stages of a plurality of boundary acoustic wave resonators may be connected in series between them.

### Second Preferred Embodiment

The difference between the second preferred embodiment of the present invention and the first preferred embodiment is in the setting of wavelengths determined by pitches in IDTS in the fourth boundary acoustic wave resonator 16 and the eighth boundary acoustic wave resonator 22.

That is, in the second preferred embodiment, the wavelength of the fourth boundary acoustic wave resonator 16 is preferably set to about 1.447 μm, for example, and the wavelength of the eighth boundary acoustic wave resonator 22 is preferably set to about 1.423 μm, for example. Accordingly, since the wavelengths of the fourth boundary acoustic wave resonator 16 and the eighth boundary acoustic wave resonator 22 are different from each other, the anti-resonant frequencies of these boundary acoustic wave resonators are also different from each other.

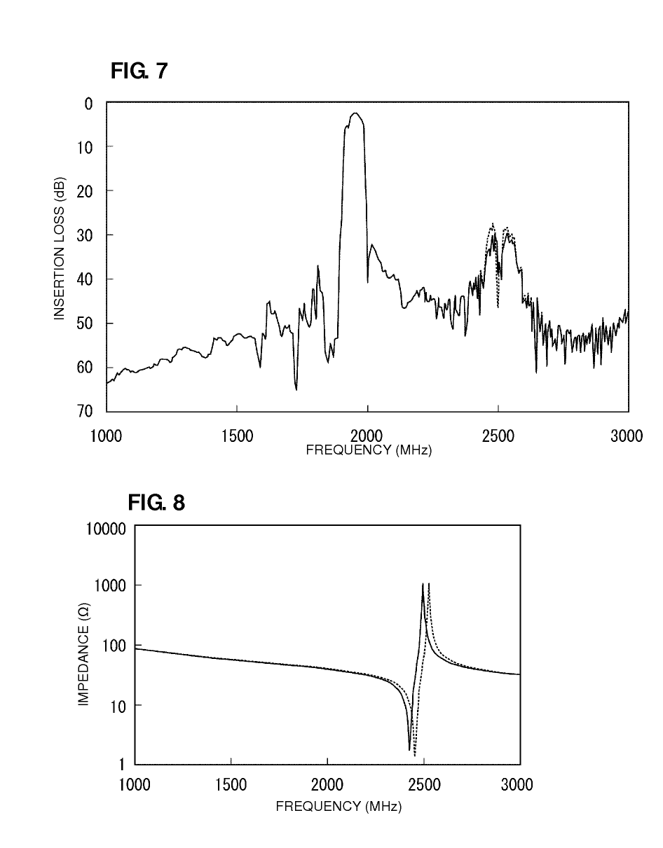

FIG. 7 is a diagram illustrating the transmission characteristics of boundary acoustic wave apparatuses according to the first and second preferred embodiments. A solid line represents the transmission characteristic of a boundary acoustic wave apparatus according to the second preferred embodiment, and a broken line represents the transmission characteristic of a boundary acoustic wave apparatus according to the first preferred embodiment.

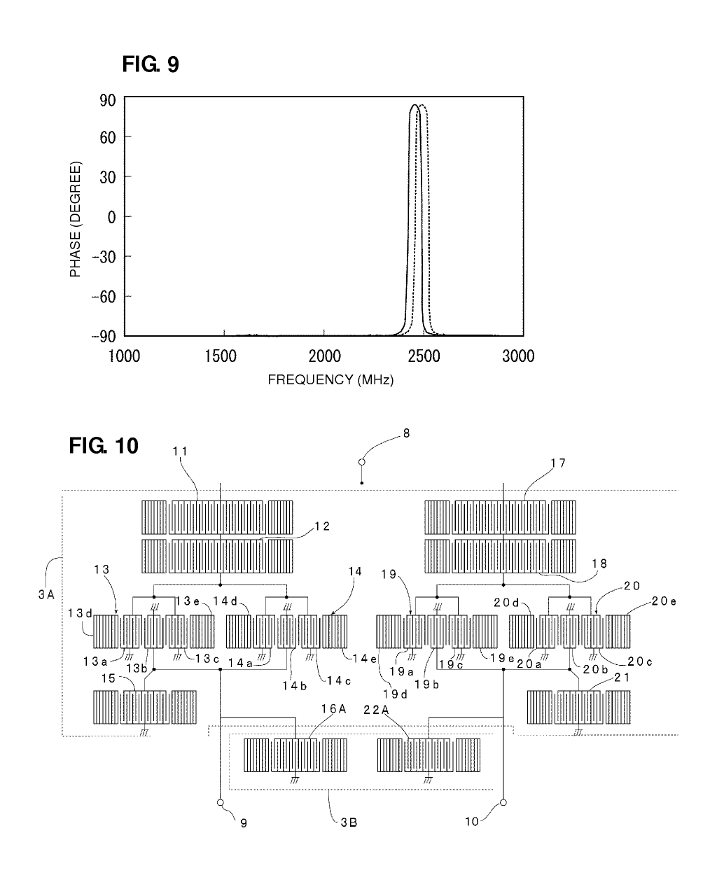

As is apparent from FIG. 7, in the first preferred embodiment, a spurious response at approximately 2.5 GHz is approximately 27 dB. On the other hand, in the second preferred embodiment, the spurious response at approximately 2.5 GHz is improved to approximately 30 dB. The reason for this will be described with reference to FIGS. 8 and 9.

FIG. 8 is a diagram illustrating the impedance characteristics of a fourth boundary acoustic wave resonator and an eighth boundary acoustic wave resonator according to the second preferred embodiment. FIG. 9 is a diagram illustrating the phase characteristics of the fourth boundary acoustic wave resonator and the eighth boundary acoustic wave resonator. As described previously, since wavelengths determined by pitches in IDTs in the fourth boundary acoustic wave resonator and the eighth boundary acoustic wave resonator are preferably set to be different from each other, the anti-resonant frequency of the eighth boundary acoustic wave resonator is higher than that of the fourth boundary acoustic wave resonator. Accordingly, a frequency band using high impedances at the anti-resonant frequencies of the fourth boundary acoustic wave resonator 16 and the eighth boundary acoustic wave resonator 22 is expanded, and the higher-order mode spurious response is more effectively suppressed.

Referring to FIG. 7, in the first preferred embodiment, the maximum amount of attenuation is approximately 47 dB and the minimum amount of attenuation is approximately 27 dB around 2.5 GHz. This result indicates that, since a frequency band in which the impedances of the fourth boundary acoustic wave resonator 16 and the eighth boundary acoustic wave resonator 22 are high is relatively narrow, the amount of attenuation can be improved in only a very narrow frequency band and the higher-order mode spurious response cannot be attenuated in a wide frequency band.

On the other hand, in the second preferred embodiment, the maximum amount of attenuation is approximately 40 dB and the minimum amount of attenuation is improved to approximately 30 dB around 2.5 GHz as described previously, since the anti-resonant frequencies of the fourth boundary acoustic wave resonator 16 and the eighth boundary acoustic wave resonator 22 are set to be different from each other and a frequency band in which the impedances of these boundary acoustic wave resonators are high is expanded.

Accordingly, as is apparent from the result in the second preferred embodiment, by using a plurality of boundary acoustic wave resonators having different anti-resonant frequencies and setting the anti-resonant frequencies to frequencies in a frequency band in which a higher-order mode response appears, the minimum amount of attenuation can be effectively improved in the frequency band in which the higher-order mode spurious response appears.

In order to improve the maximum amount of attenuation, as in the first preferred embodiment, it is preferable that the anti-resonant frequencies of a plurality of boundary acoustic wave resonators be set so as to conform to each other.

### Third Preferred Embodiment

In the first preferred embodiment, the fourth boundary acoustic wave resonator 16 and the eighth boundary acoustic wave resonator 22 that are used to suppress the higher-order mode spurious response are preferably connected in series to the first and second longitudinally coupled resonator-type boundary acoustic wave filter portions 13 and 14 and the third and fourth longitudinally coupled resonator-type boundary acoustic wave filter portions 19 and 20, respectively.

FIG. 10 is a schematic plan view illustrating the electrode structure of a boundary acoustic wave apparatus according to the third preferred embodiment of the present invention. In a boundary acoustic wave apparatus according to the third preferred embodiment, a fourth boundary acoustic wave resonator 16A and an eighth boundary acoustic wave resonator 22A that are used to suppress the higher-order mode spurious response are preferably connected in parallel to the first and second boundary acoustic wave filter portions 13 and 14 and the third and fourth boundary acoustic wave filter portions 19 and 20, respectively. That is, instead of the fourth boundary acoustic wave resonator 16 and the eighth boundary acoustic wave resonator 22 according to the first preferred embodiment, the fourth boundary acoustic wave resonator 16A and the eighth boundary acoustic wave resonator 22A are provided. Except for this point, a boundary acoustic wave apparatus according to the third preferred embodiment is preferably the same or substantially the same as a boundary acoustic wave apparatus according to the first preferred embodiment.

The fourth boundary acoustic wave resonator 16A is provided in accordance with the following specifications.

Propagation Direction: ψ=about 0 degree

Intersecting Width: about 29λ

Duty: about 0.50

Reflector: Number of Pairs: 14.5 pairs, Wavelength=about 1.375 μm

IDT: Number of Pairs: 100 pairs, Wavelength=about 1.375 μm

The eighth boundary acoustic wave resonator 22A preferably has the same or substantially the same configuration as that of the fourth boundary acoustic wave resonator 16A.

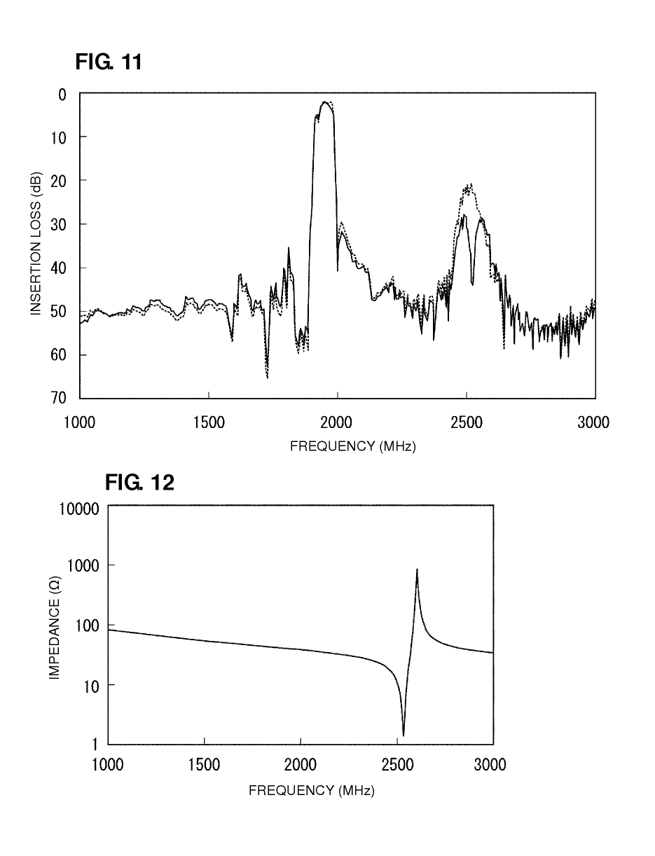

FIG. 11 is a diagram illustrating the transmission characteristics of a boundary acoustic wave apparatus according to the third preferred embodiment and a boundary acoustic wave apparatus in the related art illustrated in FIG. 3. A solid line represents the transmission characteristic of a boundary acoustic wave apparatus according to the third preferred embodiment, and a broken line represents the transmission characteristic of a boundary acoustic wave apparatus in the related art.

As is apparent from FIG. 11, in the third preferred embodiment, the amount of attenuation at approximately 2.5 GHz can be increased from approximately 20 dB in the related art to approximately 27 dB, and the higher-order mode spurious response is suppressed.

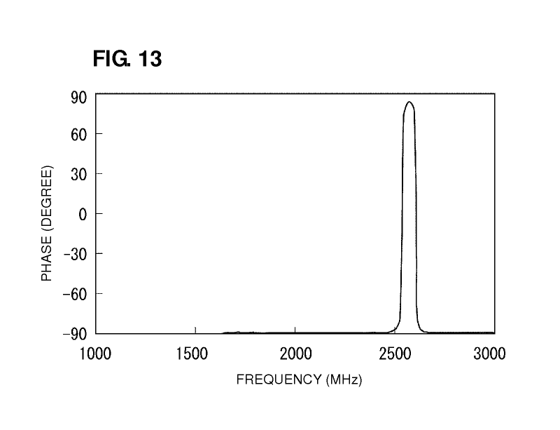

In the third preferred embodiment, as described previously, the fourth boundary acoustic wave resonator 16A and the eighth boundary acoustic wave resonator 22A are connected in parallel to the boundary acoustic wave filter portions 13 and 14 and the boundary acoustic wave filter portions 19 and 20, respectively. In addition, the resonant frequencies of the boundary acoustic wave resonators 16A and 22A are preferably set to approximately 2.5 GHz. That is, as is apparent from FIGS. 12 and 13, the resonant frequencies of the fourth boundary acoustic wave resonator 16A and the eighth boundary acoustic wave resonator 22A are set to approximately 2.5 GHz. Accordingly, using a low-impedance characteristic at the resonant frequency of the boundary acoustic wave resonator 16A or 22A, a spurious response at approximately 2.5 GHz is effectively suppressed.

As is apparent from the third preferred embodiment, a boundary acoustic wave resonator may be connected in parallel to a boundary acoustic wave filter portion. In this case, the resonant frequency of the boundary acoustic wave resonator is set to a frequency at which the maximum higher-order mode spurious response of a boundary acoustic wave filter appears.

As in the first preferred embodiment, in the third preferred embodiment, a frequency at which the extreme value of the impedance characteristic of the fourth boundary acoustic wave resonator 16A and the eighth boundary acoustic wave resonator 22A is obtained, that is, the above-described resonant frequency, may not necessarily be set so as to conform to a frequency at which the maximum higher-order mode spurious response appears, and may be located in a frequency band in which the higher-order mode spurious response appears. In this case, the higher-order mode spurious response can also be effectively suppressed with an impedance characteristic at the resonant frequency.

As is apparent from the comparison between the first preferred embodiment and the second preferred embodiment, it is possible to set a frequency band in which the higher-order mode spurious response is suppressed by using a plurality of boundary acoustic wave resonators and setting the anti-resonant frequencies of these boundary acoustic wave resonators so as to be slightly different from each other. In a case in which a plurality of parallel-connection-type boundary acoustic wave resonators are used, it is similarly possible to expand a frequency band in which the higher-order mode spurious response is suppressed by setting the resonant frequencies of these boundary acoustic wave resonators so as to be slightly different from each other.

In the first to third preferred embodiments of the present invention, a LiNbO₃ piezoelectric substrate is preferably used. A piezoelectric substrate may be made of another piezoelectric single crystal, such as LiTaO₃, or crystal, or piezoelectric ceramics such as PZT, for example. The first dielectric layer 4 is preferably made of silicon oxide, but may be made of silicon oxynitride, silicon, silicon nitride, aluminum nitride, alumina, silicon carbide, diamond, or DLC (Diamond Like Carbon), for example.

The second dielectric layer 5 may similarly be made of silicon oxide, silicon oxynitride, silicon, silicon nitride, aluminum nitride, alumina, silicon carbide, diamond, or DLC (Diamond Like Carbon), for example. It is preferable that the acoustic velocity of a material for the second dielectric layer 5 be higher than that for the first dielectric layer 4. In this case, the fundamental mode of a boundary acoustic wave can be enclosed inside the second dielectric layer 5 with certainty.

The sound absorbing layer 6 is preferably made of polyimide, but may be made of another synthetic resin such as epoxy, phenol, acrylate, polyester, silicone, or urethane, for example.

In the first to third preferred embodiments of the present invention, a boundary acoustic wave filter having the first electrode structure 3A preferably has a balanced-to-unbalanced conversion function. However, a boundary acoustic wave filter having no balanced-to-unbalanced conversion function may be provided.

In the first to third preferred embodiments of the present invention, a longitudinally coupled resonator-type boundary acoustic wave filter is preferably used. The configuration of a boundary acoustic wave filter according to preferred embodiments of the present invention is not limited thereto. For example, preferred embodiments of the present invention may also be applied to a boundary acoustic wave filter having another electrode structure, such as a ladder filter or a lattice filter, for example.

Furthermore, preferred embodiments of the present invention may be applied not only to the above-described boundary acoustic wave apparatus having a three-medium structure but also to a boundary acoustic wave apparatus having a two-medium structure in which a single dielectric layer is laminated on a piezoelectric substrate. The sound absorbing layer 6 illustrated in FIG. 2 may not be disposed.

In the first to third preferred embodiments of the present invention, a boundary acoustic wave resonator is preferably connected to a boundary acoustic wave filter. Preferred embodiment of the present invention can be applied not only to a boundary acoustic wave apparatus using a boundary acoustic wave but also to a surface acoustic wave apparatus using a surface acoustic wave. That is, a frequency at which the extreme value of a frequency characteristic of a surface acoustic wave resonator is obtained may be in a frequency band in the frequency characteristic of a surface acoustic wave filter or a boundary acoustic wave filter in which a higher-order mode spurious response appears. Alternatively, a frequency at which the extreme value of a frequency characteristic of a boundary acoustic wave resonator is obtained may be in a frequency band in the frequency characteristic of a surface acoustic wave filter in which a higher-order mode spurious response appears.

While preferred embodiments of the present invention have been described above, it is to be understood that variations and modifications will be apparent to those skilled in the art without departing from the scope and spirit of the present invention. The scope of the present invention, therefore, is to be determined solely by the following claims.

What is claimed is:

1. An elastic wave apparatus comprising:
a piezoelectric substrate;
a first dielectric layer provided on the piezoelectric substrate; and
an electrode structure provided at an interface between the piezoelectric substrate and the first dielectric layer; wherein
the electrode structure includes a first electrode structure of an elastic wave filter and a second electrode structure of an elastic wave resonator; and
a frequency at which an extreme value of a frequency characteristic of the elastic wave resonator is obtained is located in a frequency band in which a higher-order mode spurious response appears in a frequency characteristic of the elastic wave filter.

2. The elastic wave apparatus according to claim 1, wherein
the elastic wave resonator is connected in series to the elastic wave filter; and
an anti-resonant frequency of the elastic wave resonator is located in the frequency band in which the higher-order mode spurious response appears.

3. The elastic wave apparatus according to claim 1, wherein
the elastic wave resonator is connected in parallel to the elastic wave filter; and
a resonant frequency of the elastic wave resonator is located in the frequency band in which the higher-order mode spurious response appears.

4. The elastic wave apparatus according to claim 3, further comprising:
another elastic wave resonator connected in series to the elastic wave filter; wherein
an anti-resonant frequency of the another elastic wave resonator that is connected in series to the elastic wave filter is located in the frequency band in which the higher-order mode spurious response appears.

5. The elastic wave apparatus according to claim 1, wherein
a plurality of the elastic wave resonators are provided;
poles of the plurality of the elastic wave resonators are located in the frequency band in which the higher-order mode spurious response appears; and
a frequency at the pole of at least one of the plurality of the elastic wave resonators is different from a frequency at the poles of other ones of the plurality of the elastic wave resonators.

6. The elastic wave apparatus according to claim 1, wherein the elastic wave filter is a longitudinally coupled resonator-type elastic wave filter.

7. The elastic wave apparatus according to claim 1, further comprising:
a second dielectric layer laminated on the first dielectric layer.
